(19) United States
(12) Patent Application Publication
(10) Pub. No.: US 2010/0165757 A1
(43) Pub. Date: Jul. 1, 2010

(54) SEMICONDUCTOR MEMORY DEVICE

(75) Inventor: Hironobu FURUHASHI, Yokohama-Shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/562,585

(22) Filed: Sep. 18, 2009

(30) Foreign Application Priority Data
Dec. 26, 2008 (JP) 2008-334390

(51) Int. Cl. G11C 7/00; H01L 21/8242; H01L 27/108

(52) U.S. Cl. 365/189.16; 438/239; 257/296; 257/E21.646; 257/E27.084

(57) ABSTRACT

A semiconductor memory device includes a semiconductor layer; a source layer and a drain layer in the semiconductor layer; an electrically floating body region in the semiconductor layer between the source layer and the drain layer, accumulating or discharging charges for storing logical data; a gate dielectric film on the body region; and a first gate electrode and a second gate electrode on one body region via the gate dielectric film, the first and the second gate electrodes separated from each other in a channel length direction of a memory cell comprising the drain layer, the source layer, and the body region.

### CROSS-REFERENCE TO RELATED APPLICATION

This application is based upon and claims the benefit of priority from the prior Japanese Patent Applications No. 2008-334390, filed on Dec. 26, 2008, the entire contents of which are incorporated herein by reference.

### BACKGROUND OF THE INVENTION

1. Field of the Invention

The present invention relates to a semiconductor memory device.

2. Related Art

FBC (Floating Body Cell) memory devices are semiconductor memory devices expected recently as memories replacing 1T (Transistor)-1C (Capacitor) DRAMs. According to the FBC memory device, an FET (Field Effect Transistor) with a floating body (hereinafter, also body) is formed on an SOI (Silicon On Insulator) substrate, and data “1” or data “0” is stored depending on the number of majority carriers accumulated in the body. For example, in an FBC comprising an N-type FET, a state that a large number of holes are accumulated in the body is indicated as the data “1” and the state that a small number of holes are accumulated therein is indicated as the data “0”. Memory cells storing the data “0” are called “0” cells. Memory cells storing the data “1” are called “1” cells.

When the data “1” is written in a selected memory cell, the data “1” is not written in an unselected memory cell sharing a bit line with the selected memory cell. A negative potential lower than a source potential is thus applied to the gate of the unselected memory cell. When the unselected memory cell is the “0” cell, however, a drain voltage is high and a gate potential is low. A large electric field is thus applied to a body-drain pn junction. This causes GIDL (Gate Induced Drain Leakage). When a GIDL current flows in the “0” cell, holes are gradually accumulated in the body of the “0” cell and the data state in the “0” cell may be degraded (also called bit line “1” disturb).

To prevent the bit line “1” disturb, the bit line potential can be reduced during the “1” write. In this case, however, a data “1” write speed is reduced.

To prevent the bit line “1” disturb, an unselected gate potential can be increased during the “1” write. In this case, however, the data in the unselected “1” cell may be degraded.

When the data “0” is written in the selected memory cell, a negative potential lower than the source potential is applied to the gate of the unselected memory cell sharing the bit line with the selected memory cell. The drain voltage is also low. When the unselected memory cell is the “1” cell, however, holes are accumulated in the body. Thus, the body potential is higher than that of the “0” cell. Accordingly, when the body potential of the unselected memory cell is not reduced sufficiently, holes may leak from the pn junction (also called bit line “0” disturb). When the unselected memory cell is the “1” cell, the unselected gate potential is preferably reduced.

Therefore, there is a trade-off between measures for handling the bit line “1” disturb and the bit line “0” disturb.

### SUMMARY OF THE INVENTION

A semiconductor memory device according to an embodiment of the present invention comprises: a semiconductor layer; a source layer and a drain layer in the semiconductor layer; an electrically floating body region in the semiconductor layer between the source layer and the drain layer, accumulating or discharging charges for storing logical data; a gate dielectric film on the body region; and a first gate electrode and a second gate electrode on one body region via the gate dielectric film, the first and the second gate electrodes separated from each other in a channel length direction of a memory cell comprising the drain layer, the source layer, and the body region.

A method of driving a semiconductor memory device according to an embodiment of the present invention comprising a source layer, a drain layer, an electrically floating body region accumulating or discharging charges to store logical data, and a first gate electrode and a second gate electrode above one body region separated on the drain layer side and the source layer side, respectively,

the method comprises making a voltage applied to the first gate electrode be lower than a voltage applied to the second gate electrode when data is written in the memory cell.

A manufacturing method of a semiconductor memory device according to an embodiment of the present invention comprising a memory cell comprising a gate electrode, a source layer, a drain layer, and an electrically floating body region accumulating or discharging charges to store logical data,

the manufacturing method comprises: forming a gate dielectric film on a semiconductor layer provided on a buried insulation film; forming a mask material on the gate dielectric film; removing the mask material corresponding to a part where the gate electrode is to be formed in order to form a trench in the mask material; forming a material for the gate electrode on side surfaces of the trench so that a first gate electrode is formed on one side surface of the trench and a second gate electrode is formed on the other side surface thereof; forming an integrate dielectric film between the first gate electrode and the second gate electrode; removing the mask material; forming a side wall film on the respective side surfaces of the first gate electrode and the second gate electrode; and introducing an impurity using the first gate electrode, the second gate electrode, the intergate dielectric film, and the side wall film as a mask to form the source layer and the drain layer.

### BRIEF DESCRIPTION OF THE DRAWINGS

FIG. 1 is a partial plan view showing a configuration of an FBC memory according to a first embodiment of the present invention;

FIG. 2 is a cross-sectional view along a line 2-2 shown in FIG. 1;

FIG. 3 is a cross-sectional view along a line 3-3 shown in FIG. 1;

FIG. 4 is a timing diagram showing the operation of writing the data “1”;

FIG. 5 is a graph showing a result of simulation using the FBC memory of the first embodiment;

FIGS. 6, 8, 10, 12, 14 are plan views showing the manufacturing method of the FBC memory of the first embodiment;

FIGS. 7A, 7B, 9A, 9B, 11A, 11B, 13A, 13B, 15A and 15B are cross-sectional views showing the manufacturing method of the FBC memory of the first embodiment; and

FIGS. 16 and 17 are timing diagrams showing operations of the FBC memory according to the second embodiment.

### DETAILED DESCRIPTION OF THE INVENTION

Embodiments of the present invention will be explained below in detail with reference to the accompanying drawings. Note that the invention is not limited thereto.

### First Embodiment

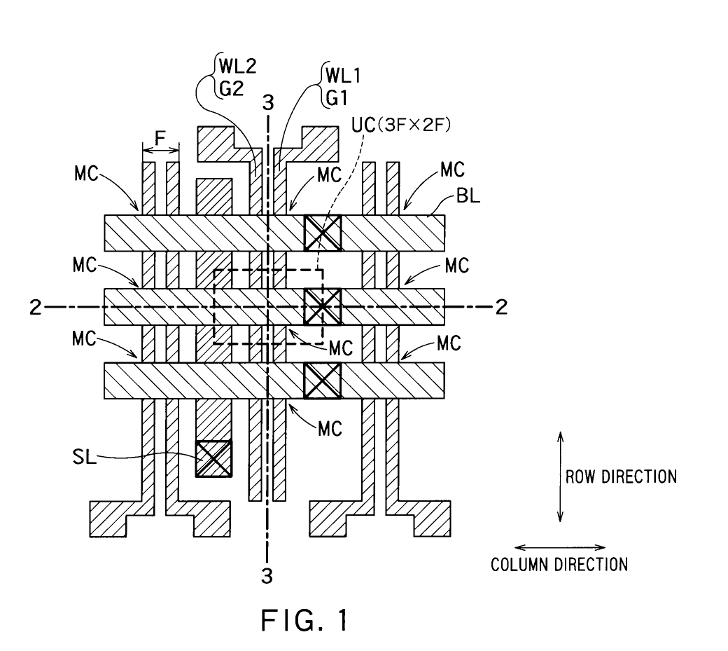

FIG. 1 is a partial plan view showing a configuration of an FBC memory according to a first embodiment of the present invention. Memory cells MC are arranged in a matrix to configure a memory cell array MCA. Word lines WL1 and WL2 extend in a row direction and function as gates G1 and G2 for the memory cells MC. According to the first embodiment, two word lines (WL1 and WL2) are provided for each row of the memory cells MC. Namely, each memory cell MC includes the first gate electrode G1 and the second gate electrode G2.

The first gate electrode G1 and the second gate electrode G2 (word lines WL1 and WL2) are separated from each other and isolated by an insulator. Thus, different voltages can be applied to the first gate electrode G1 and the second gate electrode G2 (word lines WL1 and WL2), respectively.

A bit line BL extends in a column direction and is connected to drains of the memory cells MC. A pair of the word lines WL1 and WL2 is perpendicular to the bit line BL and the memory cell MC is provided at their intersection.

According to the first embodiment, a source line SL extends in the row direction like the word lines WL1 and WL2 and is connected to sources of the memory cells MC. The memory cells MC in two adjacent rows share the source line SL. The bit line BL is connected to the drains of the memory cells MC and provided so as to correspond to each arrangement of the memory cells MC in the column direction. The row direction and the column direction are determined for convenience and interchangeable.

Assume the total width of the word lines WL1 and WL2 and the width of the bit line BL are indicated by F and a contact margin is determined as 0.5F. The size of a unit memory cell UC is then calculated as 3F×2F=6F². F indicates the minimum fabrication dimension achieved using lithography.

While the FBC memory of the first embodiment includes a sense amplifier driving the bit line BL, a word line driver driving the word line WL, a source line driver driving the source line, a row decoder decoding row addresses, and a column decoder decoding column addresses, and the like, their descriptions will be omitted.

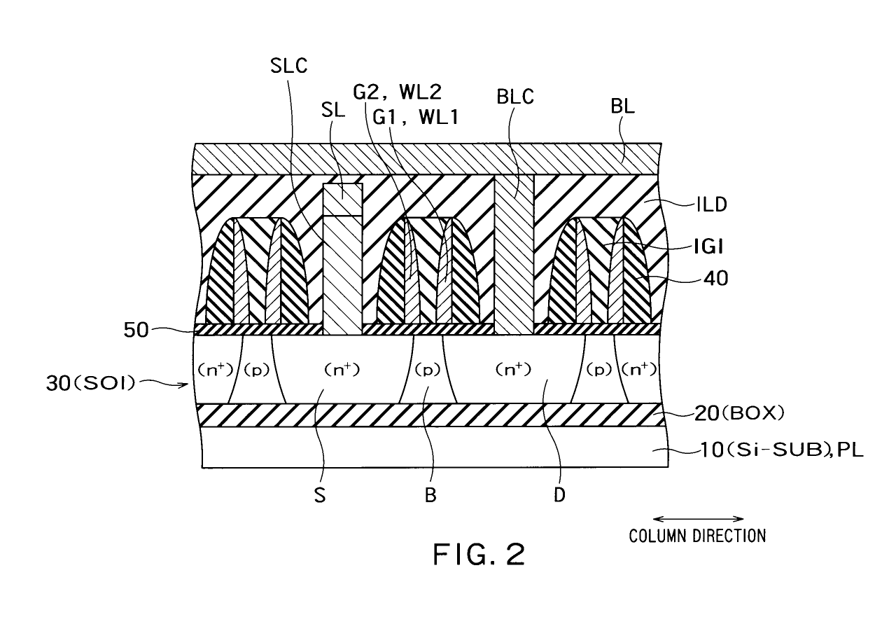

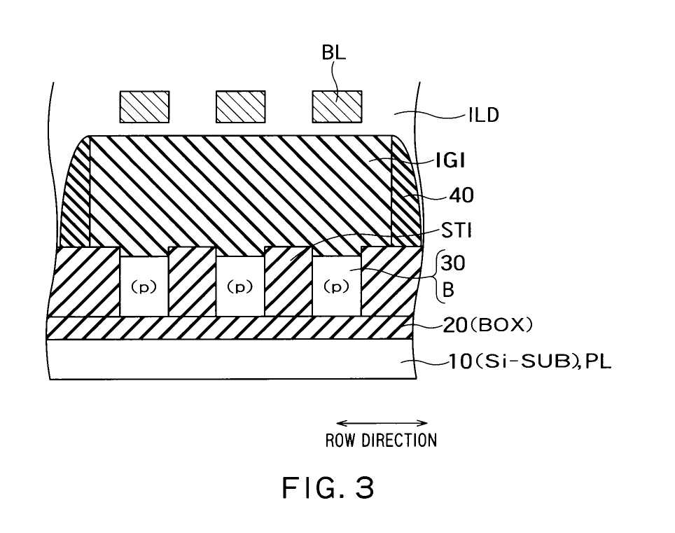

FIG. 2 is a cross-sectional view along a line 2-2 shown in FIG. 1. FIG. 3 is a cross-sectional view along a line 3-3 shown in FIG. 1. The memory cell MC is provided on an SOI substrate including a silicon substrate 10, a BOX (Buried Oxide) layer 20, and a p-type SOI layer 30. The memory cell MC has a configuration of MISFET (Metal Insulator Semiconductor Field Effect Transistor). The SOI layer 30 is formed in a stripe to constitute active areas. An STI (Shallow Trench Isolation) is buried between the active areas as shown in FIG. 3. A fixed potential is applied via plugs (not shown) to the silicon substrate 10 or a plate PL.

An n+ source S and an n+ drain D are provided in the SOI layer 30 on the BOX layer 20. A body B is formed in the SOI layer 30 between the source S and the drain D. The body B is made of semiconductors of the opposite conductive type to the source S and the drain D. The memory cell MC is an N-type FET in the first embodiment. The body B is surrounded partially or entirely by the source S, the drain D, the BOX layer 20, a gate dielectric film 50, and the STI to be in an electrically floating state. The body B accumulates or discharges majority carriers (holes) to store data. The FBC memory can store logical data (binary data) depending on the number of the majority carriers in the body B.

The source S and the drain D can include an n− extension layer (not shown) formed at the periphery of an n+ diffusion layer with a high impurity density. The source S and the drain D are formed so as to reach the BOX layer 20. Thus, the body B can keep the floating state.

The gate dielectric film 50 is provided on the body B. The first gate electrode G1 and the second gate electrode G2 are provided on the gate dielectric film 50. The first gate electrode G1 and the second gate electrode G2 are separated from each other in a channel length direction of the memory cell MC (in the same direction as the column direction in the first embodiment). The first gate electrode G1 and the second gate electrode G2 can be controlled independently. A pair of the first gate electrode G1 and the second gate electrode G2 corresponds to one row of the memory cells MC. Pairs of the first gate electrode G1 and the second gate electrode G2 correspond to rows of the memory cells MC, respectively.

An intergate dielectric film IGI is provided between the first gate electrode G1 and the second gate electrode G2. The intergate dielectric film IGI keeps the first gate electrode G1 isolated from the second gate electrode G2.

A side wall film 40 is provided on outer side surfaces of the first and the second gate electrodes G1 and G2. Further, an interlayer dielectric film ILD covers the first gate electrode G1, the second gate electrode G2, and the side wall film 40.

A source line contact SLC is provided in the interlayer dielectric film ILD so as to connect the source line SL to the source S. A bit line contact BLC is provided in the interlayer dielectric film ILD so as to connect the bit line BL to the drain D. The source line contact SLC is connected to the source S common to two memory cells MC adjacent to each other in the column direction. The bit line contact BLC is connected to the drain D common to the two memory cells MC adjacent to each other in the column direction. Further, the source line contact SLC and the bit line contact BLC are provided alternately in the column direction.

In the cross-section of the memory cell MC in the channel length direction shown in FIG. 2, the intergate dielectric film IGI has a smaller width than the channel length of the memory cell MC and is provided above the central part of the channel. The first gate electrode G1 is provided above the boundary between the drain D and the body B. The second gate electrode G2 is provided above the boundary between the source S and the body B. In other words, the boundary between the drain D and the body B exists below the first gate electrode G1. The boundary between the source S and the body B exists below the second gate electrode G2.

A method of driving the FBC memory of the first embodiment will be described. Here, data “1” is written in a selected memory cell MC. To write the data “1”, the memory cell MC is pentode-operated so that impact ionization occurs in the vicinity of the body-drain pn junction. Holes generated by the impact ionization are accumulated in the body B, so that the data “1” is written.

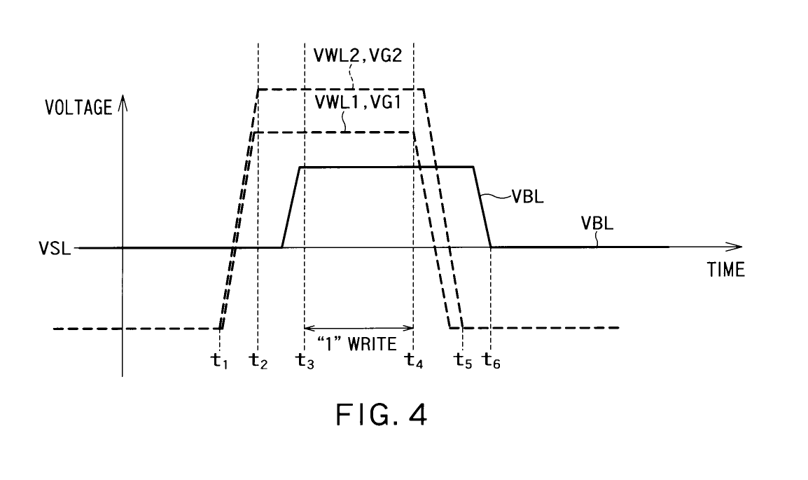

FIG. 4 is a timing diagram showing the operation of writing the data “1”. A potential VSL of the source S is the ground potential (0 V). The memory cell MC is in a data holding state before t1. Under the data holding state, the potential of the bit line BL is equal to VSL. The potentials of the word lines WL1 and WL2 (the first gate electrode G1 and the second gate electrode G2) are set to negative values lower than VSL.

The first gate electrode G1 and the second gate electrode G2 in a selected row are driven to have positive potentials at t1 to t2. Voltages VG1 and VG2 to be applied to the first gate electrode G1 and the second gate electrode G2 are different from each other. The voltage VG1 applied to the first gate electrode G1 on the drain layer D side of the memory cell MC is lower than the voltage VG2 applied to the second gate electrode G2 on the source layer S side. The voltages VG1 and VG2 are set to be larger than a threshold voltage of the memory cell MC. Thus, the memory cell MC becomes a conductive state. A relatively low voltage is applied to the body-source pn junction, while a relatively high voltage is applied to the body-drain pn junction.

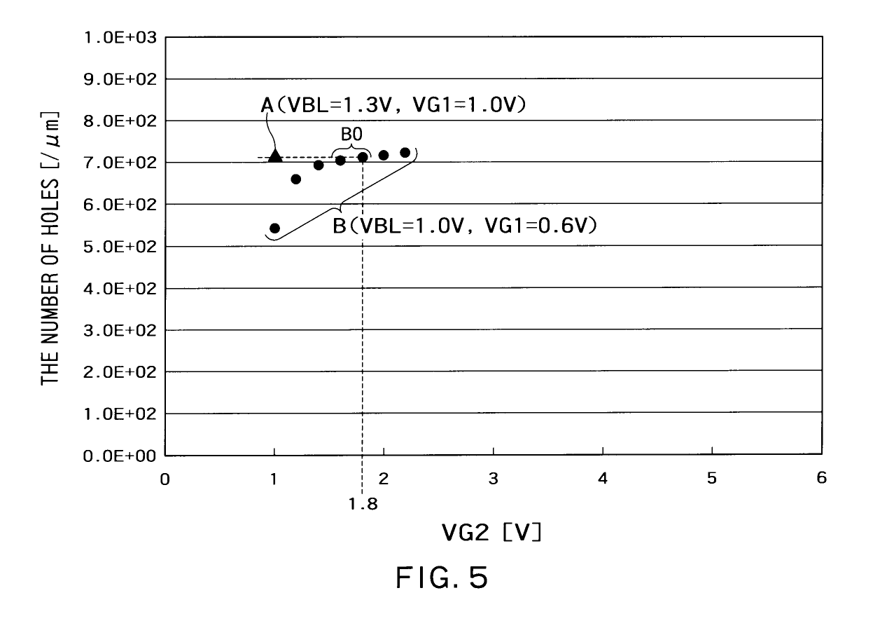

The bit line BL in a selected column is driven at t3. A positive voltage is applied to the bit line BL like the gate electrodes G1 and G2. Thus, impact ionization occurs at the body-drain pn junction, so that holes are injected in the body B. While the data “1” is written (at t3 to t4), the voltage VG2 is higher than the voltage VG1. As will be described with reference to FIG. 5, high write efficiency of the data “1” to the memory cell MC can be kept. At the same time, the voltage VBL of the bit line BL can be reduced as compared to conventional cases, so that the generation of GIDL in an unselected memory cell MC sharing the bit line BL with the selected memory cell can be suppressed. Namely, bit line “1” disturb caused by GIDL can be suppressed while keeping the high write efficiency of the data “1”.

At t4 to t5, the voltages of the first gate electrode G1 and the second gate electrode G2 return to the values in the data holding state. The voltage of the bit line BL returns to the value in the data holding state at t6.

Voltage rise or fall timings of the first gate electrode G1 and the second gate electrode G2 can be shifted from each other. To hold the written data in the “1” cell, the voltage fall timing (t5) of the first gate electrode G1 and the second gate electrode G2 is preferably prior to the voltage fall timing (t6) of the bit line BL.

FIG. 5 is a graph showing a result of simulation using the FBC memory of the first embodiment. This is the result of simulation of the data “1” write operation. The time for writing the data “1” is set to be fixed.

A point A indicates a result of a comparative example. In the comparative example, VG1 and VG2 are set to 1.0 V and VBL is set to 1.3 V. The number of holes accumulated in the memory cell MC at that time (number of holes/μm) is indicated by the point A. Because VG1=VG2 in the comparative example, the memory cell MC is probably operated substantially in the same manner as conventional FBC memory cells.

In contrast, a plot group B indicates the drive method of the first embodiment. For example, VG1 is set to 0.6 V and VBL is set to 1.0 V. The voltage VG2 of the second gate electrode G2 is varied from 1.0 V to 2.2 V. At VG2 in the range of 1.6 V to 1.8 V (at points B0), substantially the same number of holes as the one indicated by the point A in the comparative example are injected in the memory cell MC. Namely, the voltage VG2 of the second gate electrode G2 during the data “1” write is made to be higher than the voltage VG1 of the first gate electrode G1. Accordingly, the data “1” write efficiency can be kept even if the voltage VG1 and the voltage of the bit line BL during the data “1” write are made to be lower than the ones in the comparative example (conventional case).

In the first embodiment, because the voltage VBL of the bit line BL during the “1” write is lower than the one in the comparative example (conventional case), the generation of GIDL in the unselected memory cell sharing the bit line BL with the selected memory cell is suppressed. Thus, the bit line “1” disturb with respect to the “0” cell is suppressed while keeping the data “1” write efficiency.

During the “1” write, the unselected word line can be kept at a deep negative potential in the data holding state. Thus, data degradation in the unselected “1” cell is also suppressed. Namely, bit line “0” disturb is also suppressed.

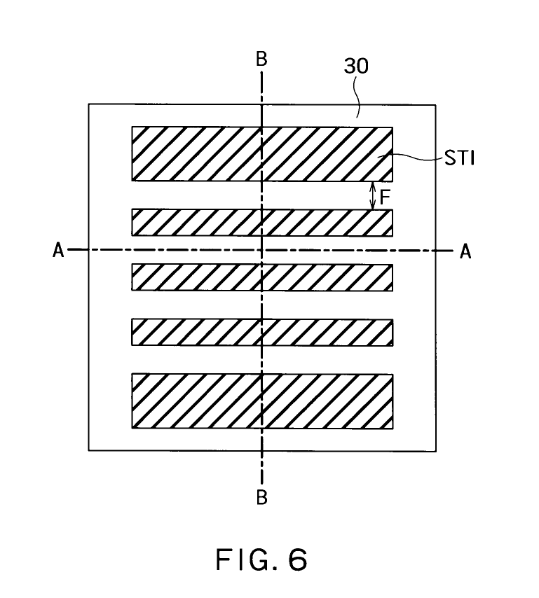

A fabrication method of an FBC memory according to the first embodiment will be described with reference to FIGS. 6 to 15B. An SOI (Silicon On Insulator) substrate is prepared first. The BOX layer 20 is provided on the silicon substrate 10. The SOI layer 30 is provided on the BOX layer 20.

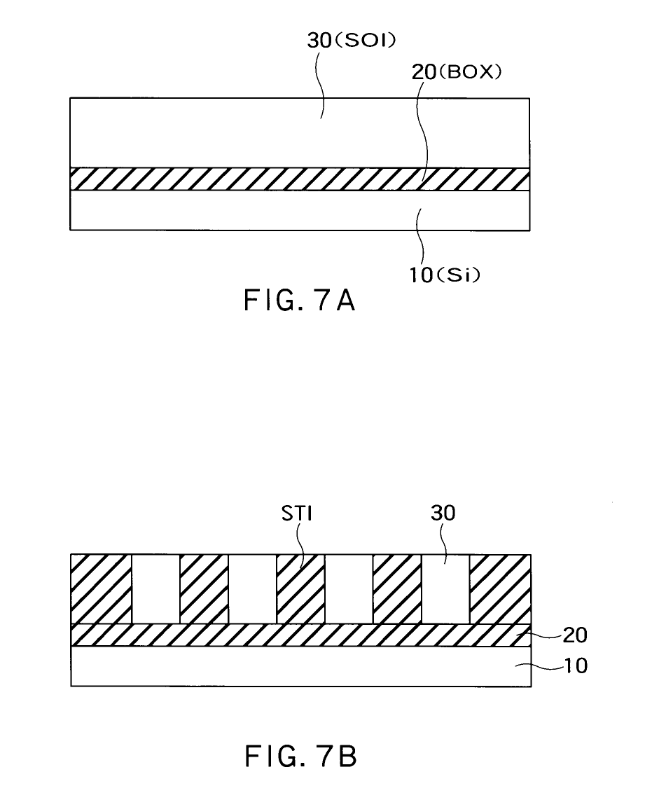

FIG. 6 is a plan view after STI (Shallow Trench Isolation) serving as isolation is formed. FIGS. 7A and 7B are cross-sectional views along a line A-A and a line B-B shown in FIG. 6, respectively. As shown in FIG. 6, the STIs are formed in stripes with a distance F therebetween. The STI has a width of F. The SOI layer 30 between adjacent STIs becomes the active area.

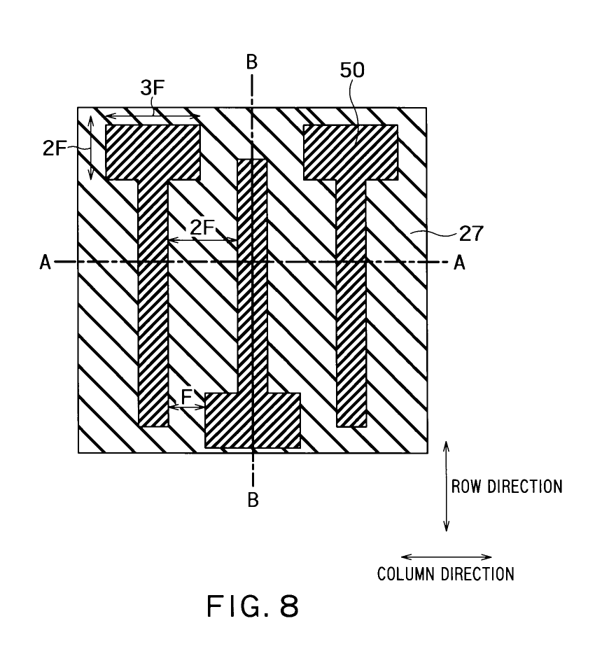

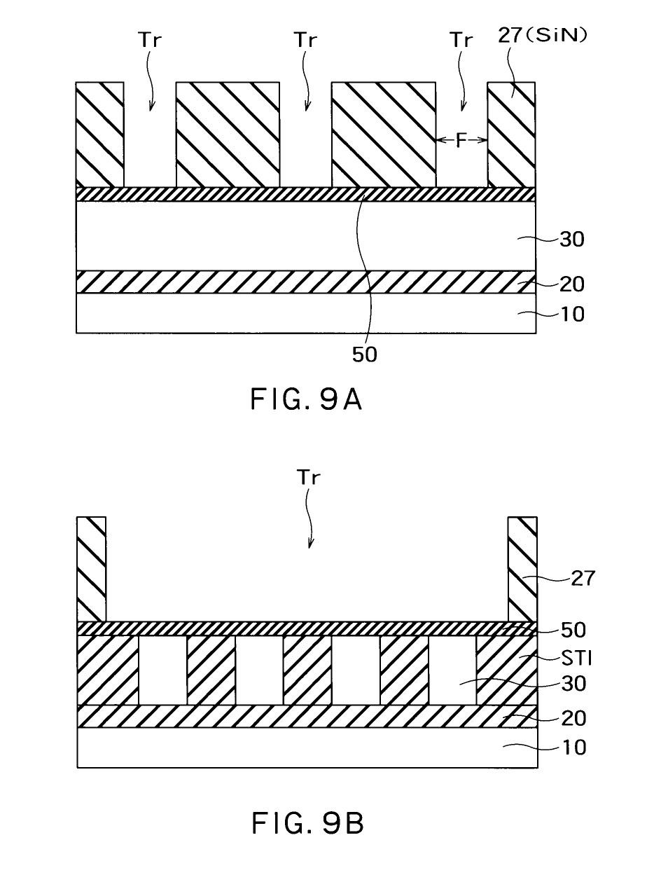

The gate dielectric film 50 is then formed on the SOI layer 30 serving as the active area. A mask material 27 is deposited on the gate dielectric film 50. The mask material 27 is made of, e.g., a silicon nitride film. The mask material 27 corresponding to the parts where the gate electrodes G1 and G2 are to be formed is removed by lithography and RIE (Reactive Ion Etching). Thus, as shown in FIGS. 8, 9A, and 9B, trenches Tr are formed in the parts where the gate electrodes G1 and G2 are to be formed. The trench Tr has a column direction width of F. A gate contact outside the cell array is etched to be a size of 3F×2F. The distance between the trenches Tr adjacent to each other in the column direction is 2F. FIGS. 9A and 9B are cross-sectional views along a line A-A and a line B-B shown in FIG. 8, respectively.

Polysilicon which is a material for the gate electrodes G1 and G2 is deposited on the mask material 27 and an inner surface of the trench Tr. At this time, the polysilicon has a thickness of less than F/2. For example, the polysilicon has a thickness of F/3. Thus, the polysilicon film can be deposited on the inner surface of the trench Tr so that the trench Tr is not buried.

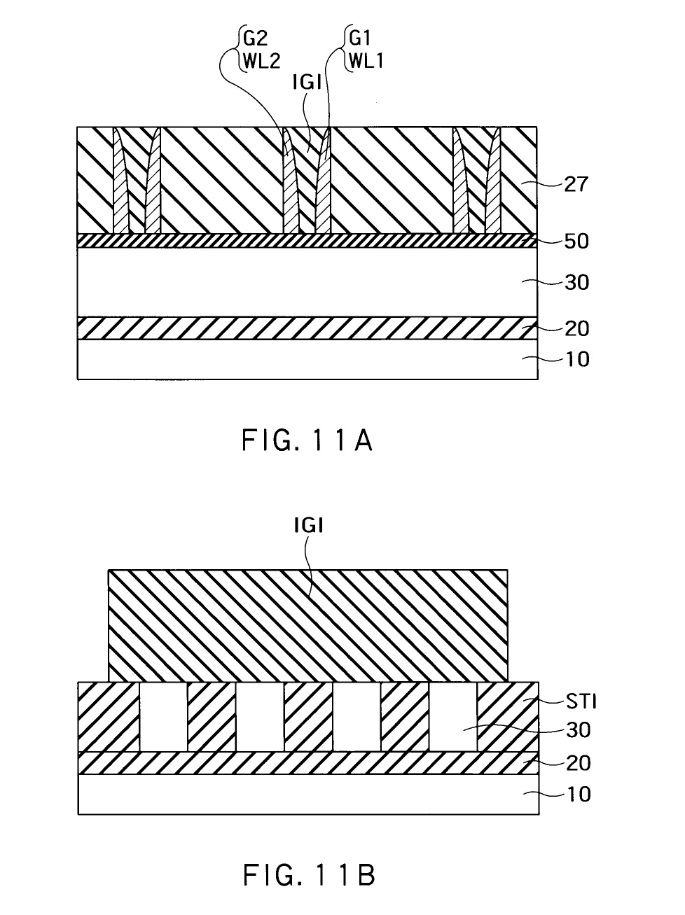

The polysilicon film is etched back, so that the polysilicon film on the bottom of the trench Tr and on the mask material 27 is removed. The polysilicon film remains at side walls of the trench Tr. As shown in FIG. 11A, the first gate electrode G1 and the second gate electrode G2 made of polysilicon are separated from each other in the trench Tr.

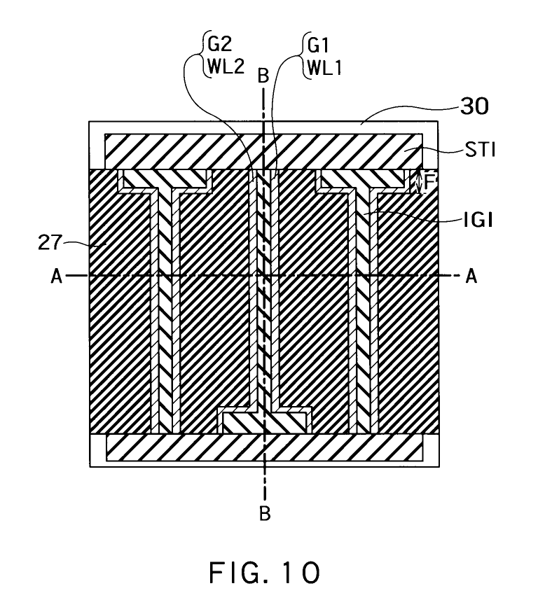

As shown in FIGS. 10, 11A, and 11B, the intergate dielectric film IGI is buried in the trench Tr. The intergate dielectric film IGI is made of, e.g., a silicon oxide film.

At this time, the polysilicon (G1, G2) continues in a loop on the inner wall surfaces of the trench Tr. To disconnect the loop of the polysilicon, as shown in FIG. 10, the mask material 27, the polysilicon film, and the intergate dielectric film IGI at the end of the word line contact area at the row direction ends of the trench Tr are etched. Thus, the first gate electrode G1 is isolated from the second gate electrode G2. FIGS. 11A and 11B are cross-sectional views along a line A-A and a line B-B shown in FIG. 10, respectively.

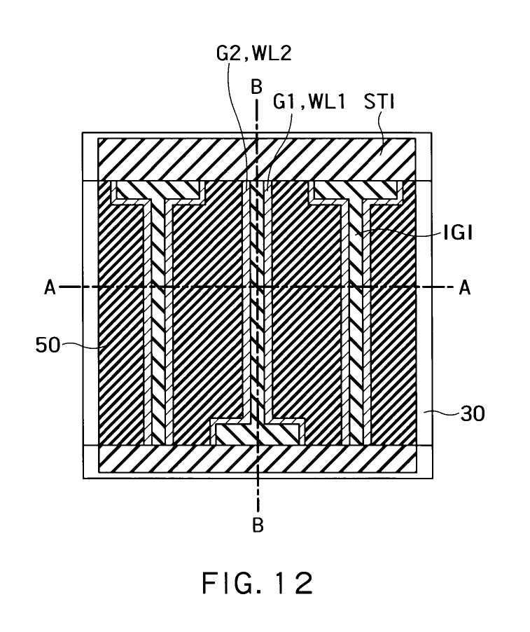

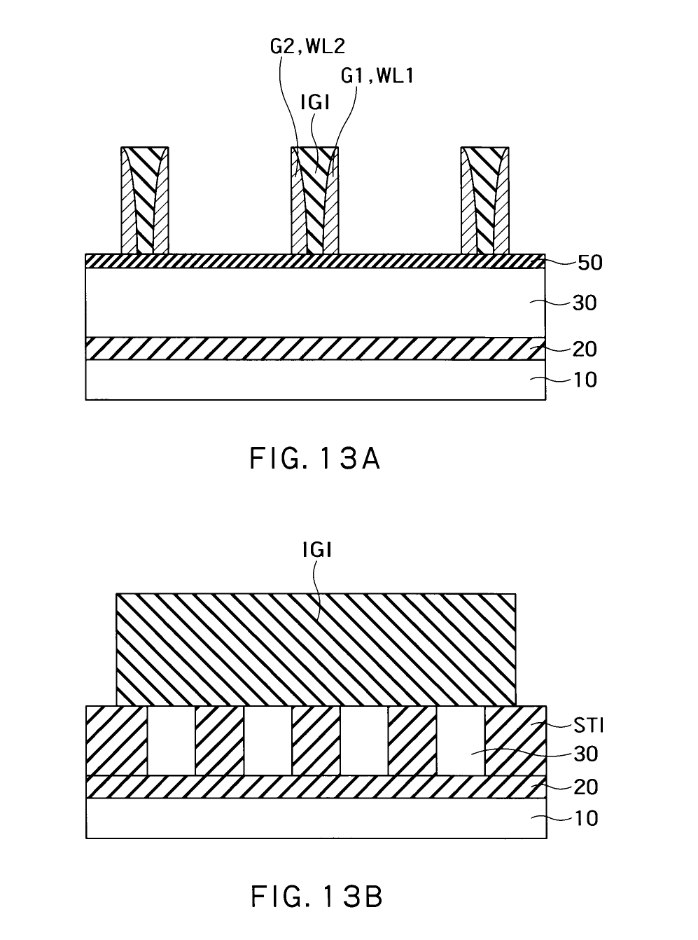

The mask material 27 is then selectively removed. A configuration shown in FIGS. 12, 13A, and 13B is obtained. FIGS. 13A and 13B are cross-sectional views along a line A-A and a line B-B shown in FIG. 12, respectively.

An n-type impurity is ion-implanted as needed using the first gate electrode G1, the second gate electrode G2, and the intergate dielectric film IGI as a mask to form an n− extension layer (not shown). The extension layer has a lower impurity density than the diffusion layer of the source S and the drain D.

A material for the side wall film 40 is then deposited on the side surface of the first gate electrode G1, the side surface of the second gate electrode G2, the top surface of the intergate dielectric film IGI, and the gate dielectric film 50. The material for the side wall film 40 is, e.g., a silicon nitride film. At this time, the thickness of the silicon nitride film is preferably less than F so that the space between the gate electrodes of the adjacent memory cells MC is not buried.

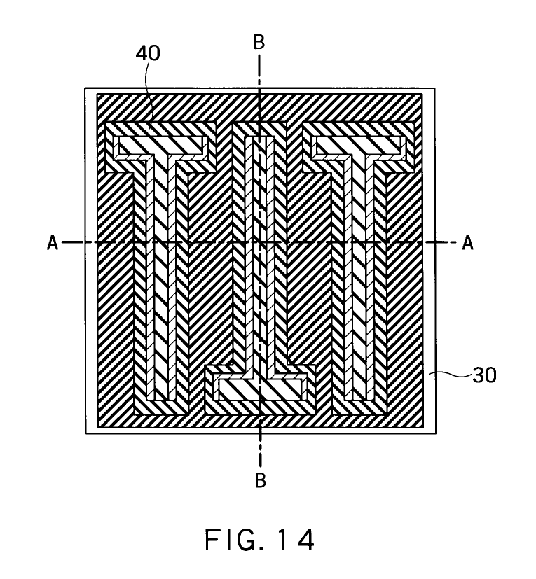

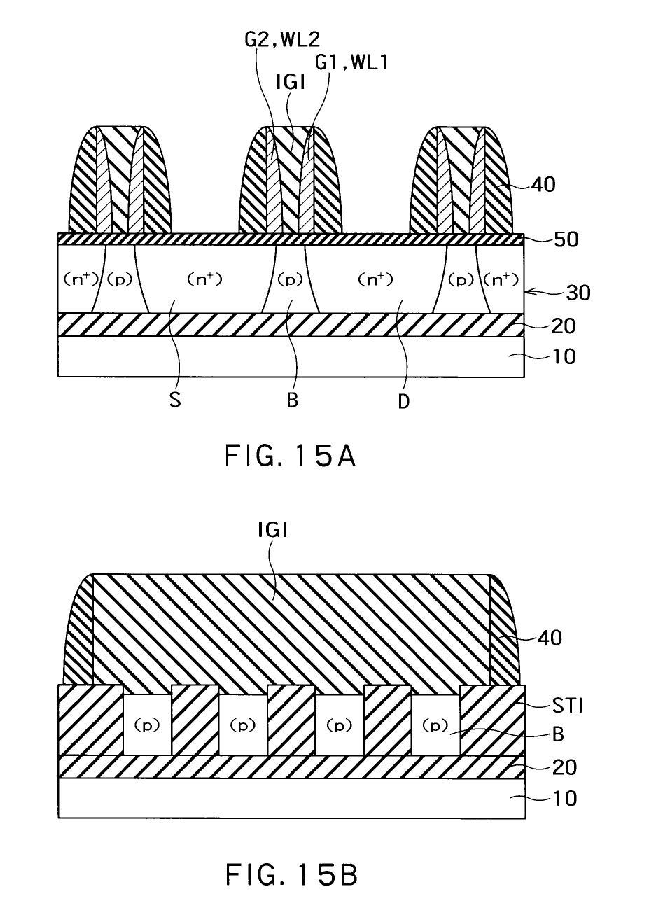

An n-type impurity is introduced using the first gate electrode G1, the second gate electrode G2, the intergate dielectric film IGI, and the side wall film 40 as a mask, so that the n− source layer and the n+ drain layer are formed in a self alignment manner as shown in FIGS. 14, 15A, and 15B.

Thereafter, the interlayer dielectric film ILD is deposited and the source line contact SLC, the bit line contact BLC, the source line SL, and the bit line BL are formed. As a result, the FBC memory of the first embodiment is completed.

### Second Embodiment

A second embodiment of the present invention is different from the first embodiment in the driving method. A configuration and a fabrication method of an FBC memory according to the second embodiment can be the same as in the first embodiment.

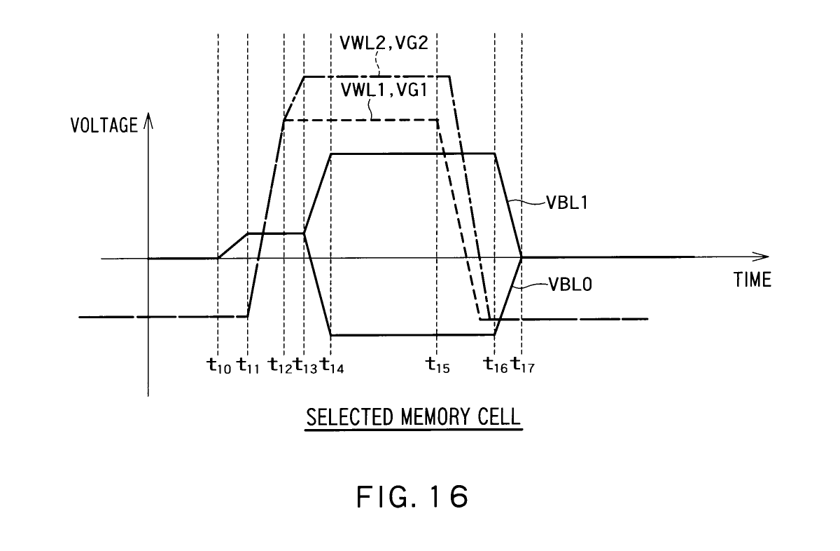

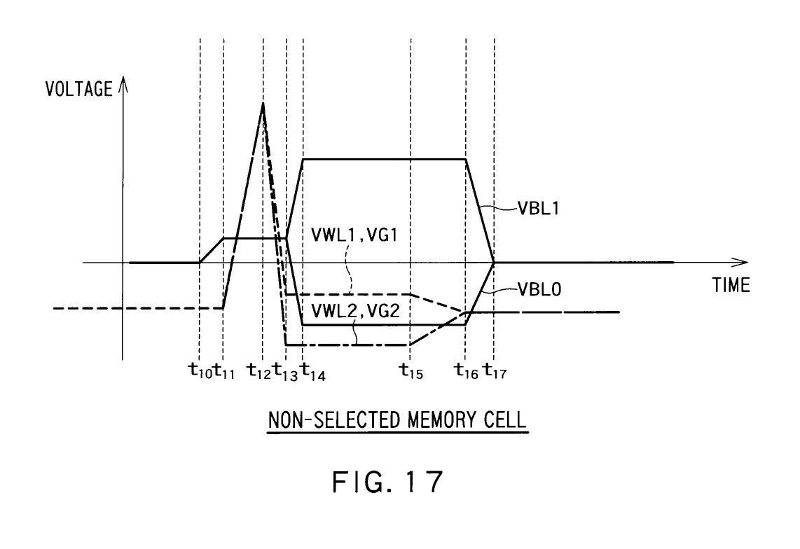

FIGS. 16 and 17 are timing diagrams showing operations of the FBC memory according to the second embodiment. FIG. 16 shows the potentials of the word lines WL1 and WL2 and the bit line BL in a selected memory cell MC in which data is to be written. FIG. 17 shows the potentials of the word lines WL1 and WL2 and the bit line BL in an unselected memory cell MC sharing the bit line BL with the selected memory cell MC, in which the data is not to be written.

The sense amplifier detects the data in the memory cell MC at t10 to t12. At t10 to t12, the operation of the selected memory cell is the same as that of the unselected memory cell.

The voltage VG1 of the first gate electrode G1 is set to be lower than the voltage VG2 of the second gate electrode G2 at t13 in the selected memory cell like the first embodiment. Thereafter, the method of driving the selected memory cell shown in FIG. 16 is the same as in the first embodiment. A voltage VBL1 is the voltage of the bit line BL when the data “1” is written. A voltage VBL0 is the voltage of the bit line BL when the data “0” is written.

The method of driving the unselected memory cell shown in FIG. 17 will be described. At t13 to t15, the voltage VG1 of the first gate electrode G1 and the voltage VG2 of the second gate electrode G2 fall to be lower than the source potential VSL. The voltage VG1 is set to be higher than the voltage VG2. Because the voltage VG1 is relatively high, the electric field applied to the body-drain pn junction in the unselected memory cell in which the potential VBL1 is applied to the drain D is softened. Thus, GIDL in the unselected “0” cell can be suppressed. Further, the data degradation in the “0” cell can be suppressed.

Because the voltage VG2 is relatively low, the body potential of the unselected memory cell can be kept low so that a forward bias is not applied to the body-drain pn junction in the unselected “1” cell. Accordingly, data degradation can be also suppressed in the unselected “1” cell.

While the memory cell MC is an n-type FET in the above embodiments, a p-type FET can be used instead. In this case, the potentials of the word lines WL1 and WL2 and the bit line BL have the opposite polarities with reference to the source potential VSL. In the above embodiments, the first gate electrode G1 and the second gate electrode G2 indicate substantially the same elements as the first word line WL1 and the second word line WL2, respectively.

1. A semiconductor memory device comprising:
a semiconductor layer;
a source layer and a drain layer in the semiconductor layer;
an electrically floating body region in the semiconductor layer between the source layer and the drain layer, accumulating or discharging charges for storing logical data;
a gate dielectric film on the body region; and
a first gate electrode and a second gate electrode on one body region via the gate dielectric film, the first and the second gate electrodes separated from each other in a channel length direction of a memory cell comprising the drain layer, the source layer, and the body region.

2. The device of claim 1, wherein the first gate electrode is isolated from the second gate electrode.

3. The device of claim 2 further comprising an intergate dielectric film between the first gate electrode and the second gate electrode.

4. The device of claim 1, wherein in a cross-section along the channel length direction, a boundary between the drain layer and the body region is located below the first gate electrode and a boundary between the source layer and the body region is located below the second gate electrode.

5. The device of claim 2, wherein in a cross-section along the channel length direction, a boundary between the drain layer and the body region is located below the first gate electrode and a boundary between the source layer and the body region is located below the second gate electrode.

6. The device of claim 1, wherein a voltage applied to the first gate electrode is different from a voltage applied to the second gate electrode when data is written in the memory cell.

7. The device of claim 2, wherein a voltage applied to the first gate electrode is different from a voltage applied to the second gate electrode when data is written in the memory cell.

8. The device of claim 3, wherein a voltage applied to the first gate electrode is different from a voltage applied to the second gate electrode when data is written in the memory cell.

9. The device of claim 4, wherein a voltage applied to the first gate electrode is different from a voltage applied to the second gate electrode when data is written in the memory cell.

10. The device of claim 4, wherein a voltage applied to the first gate electrode is lower than a voltage applied to the second gate electrode when data is written in the memory cell.

11. The device of claim 10, wherein a voltage applied to the first gate electrode is equal to or higher than a threshold voltage of the memory cell when data is written in the memory cell.

12. The device of claim 10, wherein impact ionization occurs in the boundary between the drain layer and the body region when data indicating a state that the charges are accumulated is written in the memory cell.

13. The device of claim 1, wherein voltages applied to the first and second gate electrodes are lower than a potential of the source layer and the voltage applied to the first gate electrode is higher than the voltage applied to the second gate electrode in an unselected memory cell in which the data is not written, during a data write operation.

14. The device of claim 4, wherein voltages applied to the first and second gate electrodes are lower than a potential of the source layer and the voltage applied to the first gate electrode is higher than the voltage applied to the second gate electrode in an unselected memory cell in which the data is not written, during a data write operation.

15. The device of claim 10, wherein voltages applied to the first and second gate electrodes are lower than a potential of the source layer and the voltage applied to the first gate electrode is higher than the voltage applied to the second gate electrode in an unselected memory cell in which the data is not written, during a data write operation.

16. A method of driving a semiconductor memory device comprising a source layer, a drain layer, an electrically floating body region accumulating or discharging charges to store logical data, and a first gate electrode and a second gate electrode above one body region separated on the drain layer side and the source layer side, respectively,
the method comprising:
making a voltage applied to the first gate electrode be lower than a voltage applied to the second gate electrode when data is written in the memory cell.

17. The method of claim 16, wherein the voltage applied to the first gate electrode is equal to or larger than a threshold voltage of the memory cell.

18. The method of claim 16, wherein the voltages applied to the first and second gate electrodes are lower than a potential of the source layer and the voltage applied to the first gate electrode is higher than the voltage applied to the second gate electrode in an unselected memory cell in which the data is not written.

19. A manufacturing method of a semiconductor memory device comprising a memory cell comprising a gate electrode, a source layer, a drain layer, and an electrically floating body region accumulating or discharging charges to store logical data, the manufacturing method comprising:
forming a gate dielectric film on a semiconductor layer provided on a buried insulation film;
forming a mask material on the gate dielectric film;
removing the mask material corresponding to a part where the gate electrode is to be formed in order to form a trench in the mask material;
forming a material for the gate electrode on side surfaces of the trench so that a first gate electrode is formed on one side surface of the trench and a second gate electrode is formed on the other side surface thereof;
forming an intergate dielectric film between the first gate electrode and the second gate electrode;
removing the mask material;
forming a side wall film on the respective side surfaces of the first gate electrode and the second gate electrode; and
introducing an impurity using the first gate electrode, the second gate electrode, the intergate dielectric film, and the side wall film as a mask to form the source layer and the drain layer.

20. The manufacturing method of claim 19 further comprising:
introducing an impurity using the first gate electrode, the second gate electrode, and the intergate dielectric film as a mask after the mask material is removed and before the side wall film is formed so as to form an extension layer with an impurity density lower than the source layer and the drain layer.
